(19) United States
(12) Patent Application Publication
(10) Pub. No.: US 2019/0137265 A1
(43) Pub. Date: May 9, 2019

(54) METHOD AND SYSTEM FOR THE OPTICAL INSPECTION AND MEASUREMENT OF A FACE OF AN OBJECT

(71) Applicant: UNITY SEMICONDUCTOR, Montbonnot-Saint-Martin (FR)

(72) Inventors: Jean-François BOULANGER, Vergèze (FR); Benoît THOUY, Montpellier (FR)

(73) Assignee: Unity Semiconductor, Montbonnot-Saint-Martin (FR)

(21) Appl. No.: 16/092,751

(22) PCT Filed: Apr. 5, 2017
(86) PCT No.: PCT/EP2017/058145

§ 371 Date: Oct. 10, 2018

(30) Foreign Application Priority Data
Apr. 11, 2016 (FR) 1653158

(51) Int. Cl. G01B 11/24; G01B 9/02; G01B 11/06; H01L 21/66

(52) U.S. Cl. CPC G01B 11/2441; G01B 9/0209; G01B 9/02084; G01N 21/9501; H01L 22/12; G01B 2210/56; G01B 11/0608

(57) ABSTRACT

A method for the inspection and measurement of a face of an object having at least two surfaces staggered depthwise with respect to one another, the surfaces forming in particular a step or a trench on/in the face, the method including the following steps:
measuring an interferometric signal, called measured signal, at several points, called measurement points, of the inspected face;
for at least one measurement point, extracting the measured signal relative to at least one, in particular to each, surface, the extraction providing for the measurement point an interferometric signal, called individual signal, for the surface;
profilometric analysis of the individual signals, independently for each surface.

Also included is a system for the inspection and measurement of a face of an object implementing such a method.

### TECHNICAL FIELD

The present invention relates to a method for the optical inspection and measurement of a face of an object, in particular for imaging patterns present on said face. It also relates to a system for the inspection of a face of an object implementing such a method.

The field of the invention is more particularly, but non-limitatively, that of optical profilometry.

### STATE OF THE ART

Optical profilometry makes it possible to inspect a face of an object in order in particular to detect and to image patterns, such as for example steps or trenches present on said face.

It is based on the measurement, then the study, of an interferometric signal obtained between a reference optical radiation and an inspection optical radiation originating from one and the same source, sent to the inspected face and reflected by said face. By relatively varying the optical path of the reference or inspection radiations, it is possible to determine from analysis of interference fringes the difference in length of the optical path travelled by the reflected inspection optical radiation relative to that of the optical path of the reference radiation, and deducing from it the depth or the height of the inspected face at each measurement point in order to detect and image the patterns present on said face.

However, the current optical profilometry techniques are limited in lateral resolution by the resolution of the optical imaging system which makes it possible to image the surface of the object and the interference fringes. In particular, they do not make it possible to inspect or carry out measurements on narrow patterns of characteristic dimensions close to the resolution limit of the optical system, even with a lens with a high enlargement factor such as a 50× lens. In this case,

the interferometric signal obtained cannot be suitably exploited as the items of information relating to two adjacent surfaces of different depths, such as for example the two surfaces of a trench or a step, are invariably mixed together.

An objective of the present invention is to propose a method and a system for the inspection and measurement of a face of an object more accurately.

Another objective of the present invention is to propose a method and a system for the inspection and measurement of a face of an object making it possible to detect and image narrow patterns with accuracy without the use of expensive optical means.

Another objective of the present invention is to propose a method and a system for the inspection and measurement of a face of an object making it possible to detect and image with accuracy narrow patterns the characteristic dimensions of which are of the order of or less than the resolution limit of the optical imaging system.

It is also an objective of the present invention to propose a method and a system for the inspection and measurement of a face of an object making it possible to image narrow patterns with current inspection instruments with very little or even with no modification of their hardware architecture.

### DISCLOSURE OF THE INVENTION

At least one of these objectives is achieved with a method for the inspection and measurement of a face of an object comprising at least two surfaces staggered depthwise with respect to one another, said surfaces forming in particular a step or a trench on or in said face, said method comprising the following steps:
measuring an interferometric signal, called measured signal, at several points, called measurement points, of said inspected face;
for at least one, in particular each, measurement point, extracting the measured signal relative to at least one, in particular to each, surface, said extraction providing for said measurement point an interferometric signal, called individual signal, for said surface, in particular for each surface;
profilometric analysis of the individual signals, independently for each surface.

Such an extraction step, proposed by the method according to the invention, is particularly useful when the measurement point is located at the level of an interface between two adjacent surfaces of different depths. In fact, in this case, the measured interferometric signal contains, mixed together, items of information relating to each of the adjacent surfaces.

The method according to the invention thus proposes to isolate, individually, the item of information relating to each surface constituting the inspected face, by selecting from the measured interferometric signal, the part of said measured signal corresponding to each surface, before the step of profilometric analysis. Once isolated, each individual interferometric signal can be analysed according to a known profilometry technique.

Thus, the method according to the invention makes it possible to reduce or even undo the mixtures of items of information relating to two adjacent surfaces of different depths, in particular at the interface of these two surfaces, which makes it possible to carry out a more accurate inspection of a face of an object.

In addition, by reducing the mixtures of items of information relating to two adjacent surfaces of different depths, in particular at the level of the interface of these two surfaces, the method according to the invention makes it possible, with a given optical imaging system and a sensor, to image patterns of smaller dimensions, in particular narrower, compared with the methods of the state of the art.

Moreover, the extraction step can be carried out by digital or analogue processing, and has little or no impact on the signal measurement steps. Consequently, the method according to the invention can be implemented by the current inspection or measurement devices with very little or no architectural modification, in particular of the optical part of these devices.

In other words, the method according to the invention makes it possible to push back the lateral resolution limit imposed by the optical imaging system and the sensor, by allowing the inspection and the dimensional measurement of patterns with characteristic dimensions of the order of or less than this resolution limit,

which could not be inspected or measured by this optical system otherwise.

The extraction step can be implemented for all the measurement points.

Alternatively, the extraction step can be implemented for the measurement points only, located at the level of an interface between two adjacent surfaces of different depths.

Advantageously, the step of measuring the interferometric signal can carry out a measurement of an interferometric signal for each pixel of a sensor carrying out a full-field measurement.

In this case, each pixel can correspond to a measurement point for which an interferometric signal is measured.

Advantageously, the method according to the invention can moreover comprise a step of, independently constructing each surface as a function of the profilometric analysis of the individual signals from said surface.

In fact, by exploiting the depth detected in each individual interferometric signal for each measurement point, it is possible to merge the individual signals relating to this surface and construct this surface independently.

In order to do this, each measurement point is positioned at the depth detected for said measurement point in the individual interferometric signal relating to said measurement point.

Moreover, the method according to the invention can furthermore comprise a step of constructing a representation of the inspected face, and in particular a three-dimensional representation of said face, comprising the patterns found on said inspected face.

Such a construction, in particular three-dimensional, can be produced by concatenation of the measured depth values in each individual signal at the level of each measurement point, and for the surfaces in their entirety.

In other words, such a construction can be produced by concatenation of the measurement points, at the depths detected in the individual interferometric signals for the surfaces in their entirety

In a particularly advantageous version, the step of constructing a representation of the inspected face can be produced from the individual representations of the surfaces.

In this case, the construction step can comprise, for at least one measurement point, an iteration of the following steps:
determining a signal quality value, at said measurement point, in at least two individual representations, and
allocating said measurement point to one the surfaces, as a function of the signal quality values obtained for each of said two individual representations.

In particular, these steps can be carried out for at least one, in particular each, measurement point allocated to two adjacent surfaces of different depths. In this case, the individual representations considered are those of said adjacent surfaces.

Thus, the method according to the invention makes it possible to determine a three-dimensional representation of the inspected face with greater accuracy.

In fact, it can happen that a measurement point which is located at the level of the interface between two adjacent surfaces of different depths is allocated to each of these two surfaces. In this case, a standard three-dimensional representation would show said measurement point in each of these adjacent surfaces. This would be incorrect. The method according to the invention makes it possible to avoid such a double allocation, by distinguishing on the basis of the quality of the signal obtained for each of the adjacent surfaces, and allocating the measurement point to one of the adjacent surfaces only.

In a non-limitative embodiment, the allocation step can be carried out by a predetermined comparison relationship taking into account:
the signal quality values of each individual representation, and
a multiplier coefficient applied to a signal quality value of an individual representation.

Thus, the method according to the invention makes it possible to allocate a measurement point to a surface when, for said measurement point, the quality of the signal in the individual representation of one of the surfaces is greater, optionally by a multiplier coefficient, than the signal quality value in the individual representation of the other one of the surfaces.

According to a non-limitative embodiment example, the multiplier coefficient can be determined empirically or experimentally.

According to another non-limitative embodiment, the multiplier coefficient can be determined by learning, for example from reference measurements on objects of known characteristics.

Alternatively or in addition, the multiplier coefficient can be a function of at least one parameter of a measurement sensor used during the measurement step. Such a parameter of the measurement sensor can for example be a sensitivity of the sensor or a measurement uncertainty value of said sensor, for example given by the manufacturer or measured during prior tests.

Alternatively or in addition, the multiplier coefficient can be determined as a function of at least one parameter of the inspected face. Such a parameter of the inspected face can for example be a reflection/refraction value of the material used, a value of difference of theoretical depth between two adjacent surfaces, a characteristic dimension of the pattern, etc.

In a particularly preferred embodiment, for at least one surface, the profilometric analysis step can comprise for each individual signal:
a Fourier transform of said individual signal; and
an analysis of the phase of the Fourier transform obtained.

In fact, the phase of the Fourier transform of the individual interferometric signal of a simple surface is linear, and analysis of this phase makes it possible to accurately deduce an item of topographical information. On the other hand, it should be noted that this simple method does not work with an interferometric signal which comprises a mixture of items of information relating to two or more adjacent surfaces, as in this case the phase of the

Fourier transform of the interferometric signal measurement shows no such linearity.

In a version of the method according to the invention, for at least one surface, the step of extracting a measured signal relating to said surface can comprise selecting a portion of said measured interferometric signal comprising an envelope corresponding to said surface in said measured interferometric signal. This envelope can correspond to a significant local amplitude of the fringes or of the interference signals.

Such an extraction step is not very complicated to implement, requires few resources and a very short processing time.

In particular, for two adjacent surfaces of different depths, the selection step can advantageously produce a splitting of the measured interferometric signal into two portions each comprising an envelope corresponding to one of said surfaces in said measured signal, the individual signal for each surface corresponding to one of said portions.

Of course, when more than two adjacent surfaces of different depths exist for one measurement point, the splitting can be carried out by considering the adjacent envelopes in the measured signal in pairs.

Such splitting is not very complicated to implement, requires few resources and a very short processing time for the measured interferometric signal.

According to a particularly preferred embodiment, the splitting of the measured signal, for two adjacent envelopes, can be carried out at a position of said measured signal:
between said two adjacent envelopes, and
substantially equidistant from the positions of said adjacent envelopes.

The positions of the envelopes can for example correspond to their respective peaks.

For example, if the envelopes corresponding to two adjacent surfaces are separated, in the measured interferometric signal, by a distance of depth Δ, then the measured interferometric signal is

split in two at a position located between the two envelopes, at a distance Δ/2 from the position of each envelope.

In a version, the depth of each surface, and therefore the position of each envelope in the measured interferometric signal, can be provided beforehand, in particular approximately or theoretically, prior to the inspection, for example by a designer or a manufacturer of the object the face of which is inspected.

The depth of at least one surface of the inspected face can be provided relative to another surface of said surface.

Alternatively or in addition, the method according to the invention can comprise a step of estimating the position, in the measured interferometric signal, of at least one envelope corresponding to a surface, prior to the extraction step.

Such a step of estimating the position of an envelope can be carried out in different ways, by analysis of the measured interferometric signal.

In particular, the step of estimating the position of an envelope in the measured interferometric signal can comprise a step of:
demodulation of the measured interferometric signal, and/or
analysis of the energy of the measured interferometric signal, and/or
analysis of the contrast of the fringes of the measured interferometric signal.

For example, in the context of an energy analysis, the position of an envelope in the measured signal can be detected by detecting the position of a local maximum of the energy of the measured interferometric signal.

In the context of an analysis by demodulation, the position of an envelope in the measurement signal can be detected by applying a low-pass filter to the rectified signal. This low-pass filter makes it possible to eliminate the high frequency component of the rectified signal, i.e. the fringes, while retaining the low frequency component, i.e. the envelope of the signal. The rectified signal can be obtained for example with an absolute value operator, average value thresholding, squaring, or

multiplication by a carrier of the same frequency (synchronous demodulation).

In the context of an analysis of fringe contrast, the position of an envelope in the measured signal can be detected by looking for the amplitude and/or the peaks of the interference fringes, for example with comparison operators or by derivation.

According to another aspect of the same invention, a system is proposed for the inspection and measurement of a face of an object comprising at least two surfaces staggered depthwise with respect to one another, said surfaces forming in particular a step or a trench on or in said face, said system comprising:
a device for measuring an interferometric signal, called measured signal, at several points, called measurement points, of said inspected face; and
a module for processing the measured interferometric signals, configured in order to implement all the steps of the method according to the invention.

The configuration of the processing module can be carried out in an electronically and/or by computer, in particular with instructions executable by a processor or an electronic chip, of EEPROM type for example.

The processing module can be incorporated in the measurement device, or be external to the measurement device and connected to said measurement device in a wired or wireless manner.

In an advantageous version, the measurement device can comprise a full-field interferometric sensor.

In this case, a measurement point can correspond to a pixel of said sensor.

The method and the system according to the invention can each be used for the inspection of a face of a semiconductor or wafer element, in particular for measuring the depth(s) of trench(es) and/or the height(s) of step(s) present on said face, or also for imaging said face.

More generally, the method and the system according to the invention can each be used for the inspection of a face of an object, in particular for the detection and/or the characterization and/or the imaging of at least one pattern of said face.

### DESCRIPTION OF THE FIGURES AND EMBODIMENTS

Other advantages and characteristics of the invention will become apparent on examination of the detailed description of examples which are in no way limitative, and the attached drawings, in which:

FIG. 1 is a diagrammatic representation of a non-limitative embodiment example of a method according to the invention;

FIGS. 2a-2h are diagrammatic representations of a non-limitative example of the inspection and measurement of a face of an object such as a wafer with the present invention, and in particular with the method of FIG. 1; and

FIG. 3 is a diagrammatic representation of a non-limitative embodiment example of a system according to the invention.

It is well understood that the embodiments which will be described hereinafter are in no way limitative. Variants of the invention can be considered comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described can be combined together if there is no objection to this combination from a technical point of view.

In the figures, the elements that are common to several figures retain the same reference.

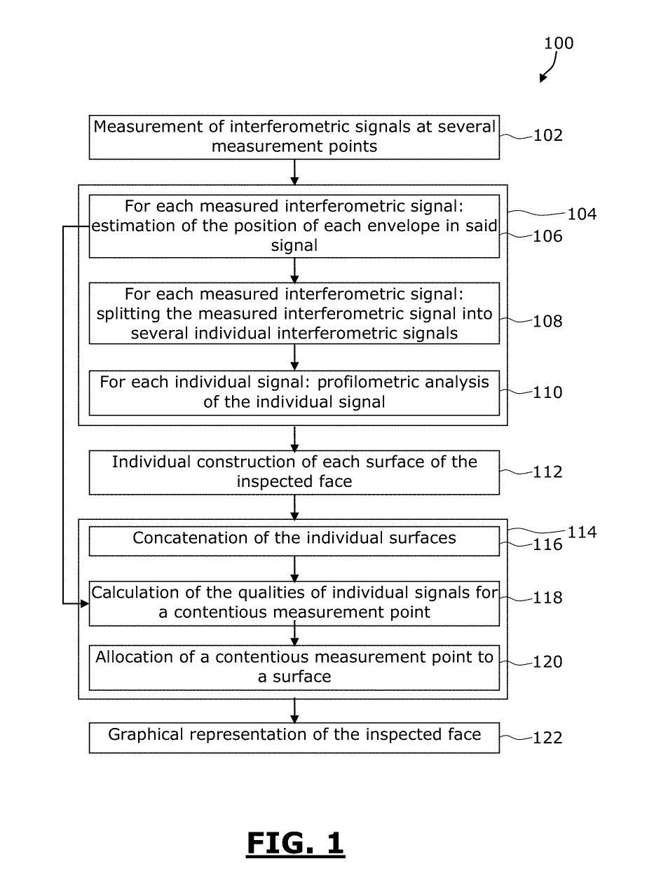

FIG. 1 is a diagrammatic representation of a non-limitative embodiment example of a method according to the invention.

The method 100, represented in FIG. 1, comprises a step 102 of measuring an interferometric signal at several measurement points on a face of an object, for example using a full-field interferometric sensor. In this case, each pixel of the sensor corresponds to a measurement point, and an interferometric signal is measured by each pixel of said sensor.

The method 100 comprises moreover a processing phase 104, carried out for each measurement point, i.e. for each measured interferometric signal.

The processing phase 104 comprises a step 106 carrying out an estimation of the position of each envelope in the measured interferometric signal. This estimation step 106 is carried out by demodulation of the measured interferometric signal by applying a low-pass filter on the rectified signal after background subtraction (or by carrying out a synchronous demodulation). The background is calculated by smoothing the signal with a sufficiently broad averaging sliding window. The low-pass filter makes it possible to remove the high-frequency components of the rectified signal while retaining the low-frequency component, i.e. the envelope. The local maxima of the demodulated signal which exceed a predetermined amplitude threshold are detected and their position stored. The amplitude threshold can be chosen, for example, in order to find a good compromise between a number of false detections and a number of non detection of envelopes, the challenge being to detect the weak signals without the noise in the interferometric signals leading to too many false detections. This detection threshold can be set or adaptive as a function, for example:
of a criterion linked to the amplitude of the demodulated signal (peak value, root mean square value) over all of the signal or in a neighbourhood; and/or
of a criterion linked to a measurement of the noise of the measured interferometric signal.

The interferometric signal is then processed, during step 108, by considering that each envelope detected during step 106 corresponds to a surface of different depth. In particular, the processing consists of splitting the interferometric signal into as many portions as there are envelopes in said measured interferometric signal. Splitting the interferometric signal is carried out between the adjacent envelopes, taken in pairs, in a position located substantially at an equal distance from the position of each of said two adjacent envelopes. For example, when the interferometric signal comprises N envelopes Eₖ, with 1≤k≤N and Dₖ the position of the envelope k in said measured interferometric signal, a first portion P₁ comprising the envelope E₁ is firstly split in a splitting position DD₁ located between the positions D₁ and D₂, and at an equal distance from the positions D₁ and D₂. Then, a second portion P₂ comprising the envelope E₂ is split: this second portion corresponds to the portion of the measured interferometric signal located between the first splitting position DD₁ and a second splitting position DD₂ located between the positions D₂ and D₃, at an equal distance from the positions D₂ and D₃, and so on. The last portion P_{N} corresponds to the portion of the measured interferometric signal located between the penultimate splitting position DD_{N-1} and the end of the measured interferometric signal.

When the measured interferometric signal comprises only two envelopes E₁ and E₂, then it is split into two portions in a splitting position DD₁ located between the positions D₁ and D₂, and at an equal distance from the positions D₁ and D₂. The first portion P₁ comprises the start of the measured signal up to the splitting position DD₁ and the second portion P₂ comprises the end of the measured signal starting from the splitting position DD₁.

Each portion obtained during the splitting step forms an individual signal for each surface of the inspected face.

During step 110, a profilometric analysis of each individual signal is carried out in order to detect the position of the surface to which the single envelope contained in the individual signal corresponds. During this step 110 each signal individual undergoes:
a Fourier transform of said individual signal; and
an analysis of the phase of the Fourier transform obtained.

The frequency domain where the phase of the Fourier transform is linear corresponds to the frequency domain of the light source of the profilometer.

In addition, the depth of the surface at the corresponding measurement point can be deduced from the slope of the phase in this frequency domain or from the value of the phase at the central frequency of the light source of the profilometer.

The processing phase 104 ends at step 110.

During step 112, as a function of the profilometric analysis of the individual signals, an individual construction of each surface of a given depth is carried out by concatenation of the measurement points detected at said depth.

During the construction of the surfaces individually, it is possible and frequent, in particular in the case where a lens with a high enlargement factor, such as a 50×, is used, that at one and the same measurement point, two different depths are detected, and that consequently this measurement point is allocated to two surfaces of different depths. Such a situation occurs in particular when the measurement point is at the limit between two adjacent surfaces of different depths.

During phase 114, a three-dimensional representation of the inspected face is carried out.

During this phase 114, step 116 carries out a concatenation/merging of the individual representations obtained during step 112, for all the measurement points.

When a contentious measurement point, denoted (i,j), is detected as belonging to two different surfaces, a step 118 determines the quality Q₁(i,j) and Q₂(i,j) of the individual measurement signal corresponding to surface 1, respectively to surface 2. This quality measurement is obtained from the maxima observed on the demodulated signal during the step of detecting the interfaces/envelopes (step 106). It corresponds for example to the maximum amplitude of the envelope of the surface considered.

Step 120 carries out an allocation of said contentious measurement point to one of the two surfaces by comparing the qualities Q₁(i,j) and Q₂(i,j). For example:
if Q₁(i,j)<β.Q₂(i,j), then the measurement point (i,j) is allocated to surface 2; and
if Q₁(i,j)≥β.Q₂(i,j), then the measurement point (i,j) is allocated to surface 1.

A weighting coefficient, or multiplier coefficient β is applied to the quality measurements in order to carry out the comparison. In the embodiment implemented, this multiplier coefficient β is determined experimentally so as to substantially compensate for the difference in light energy reflected by the different surfaces of the patterns. In fact, the base of the patterns (surface 2 in the examples presented) in general naturally reflects light less than the upper surfaces (surface 1). Thus a multiplier coefficient β>1 is chosen, such as for example β=5.

During a step 122, a graphical representation of the inspected face is produced.

The method 100 can moreover comprise analysis and statistical steps relating to the widths, heights, depths of patterns, such as steps or trenches.

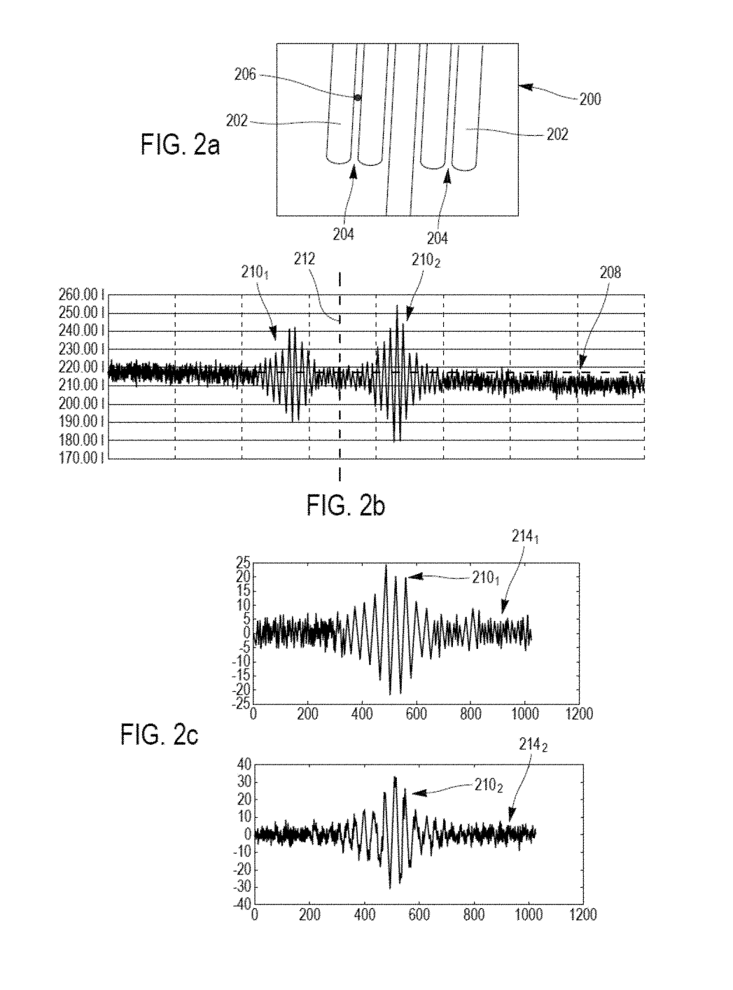

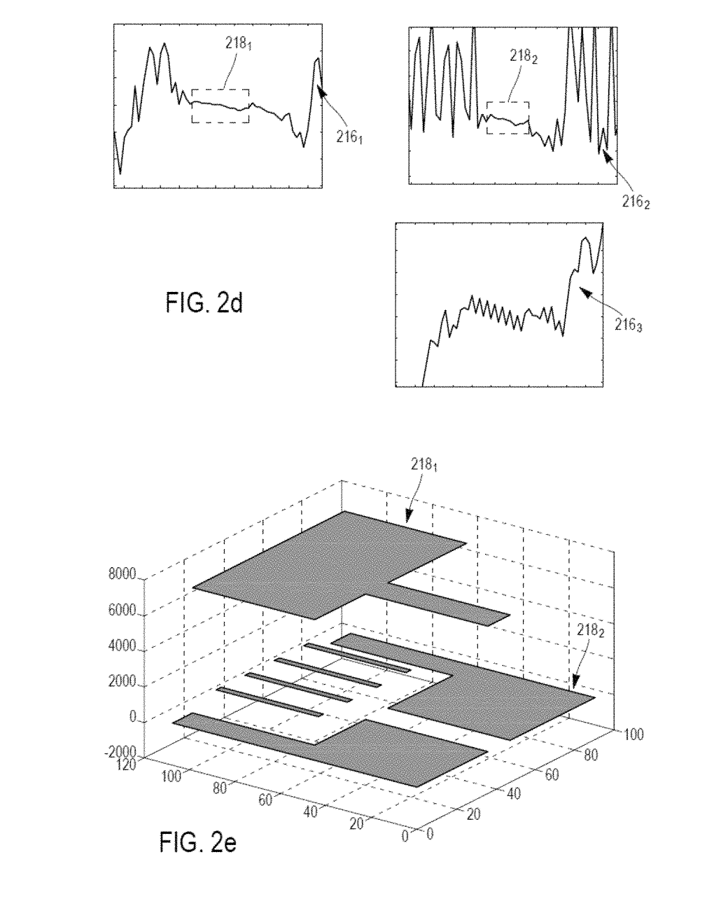

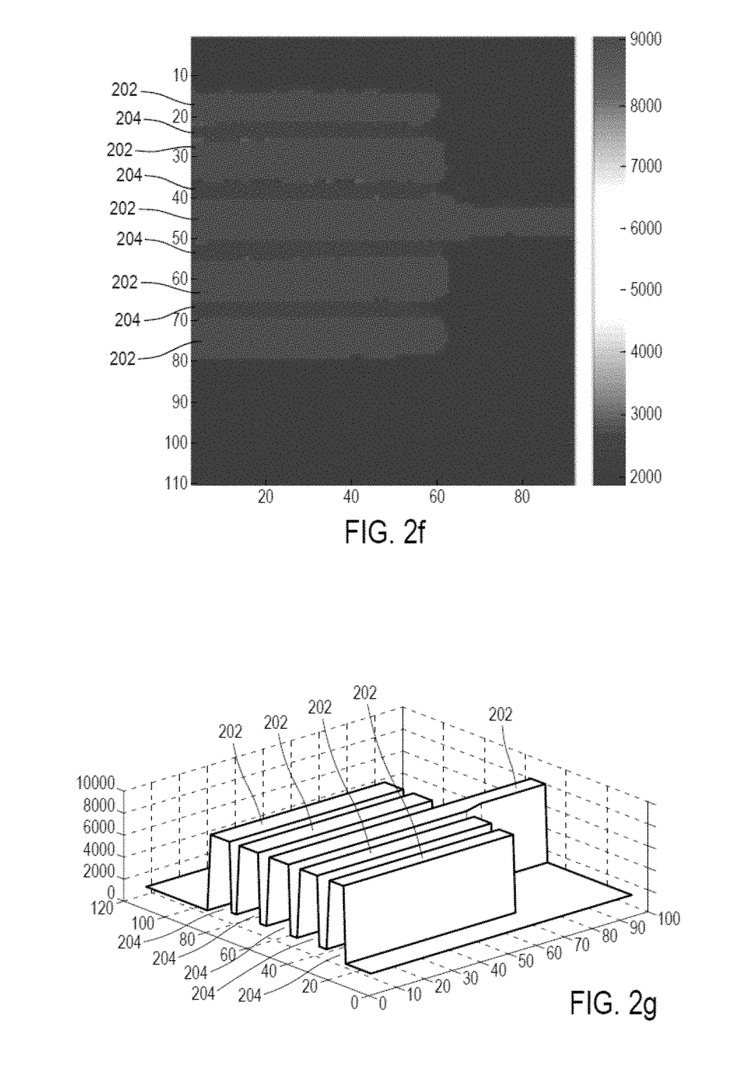

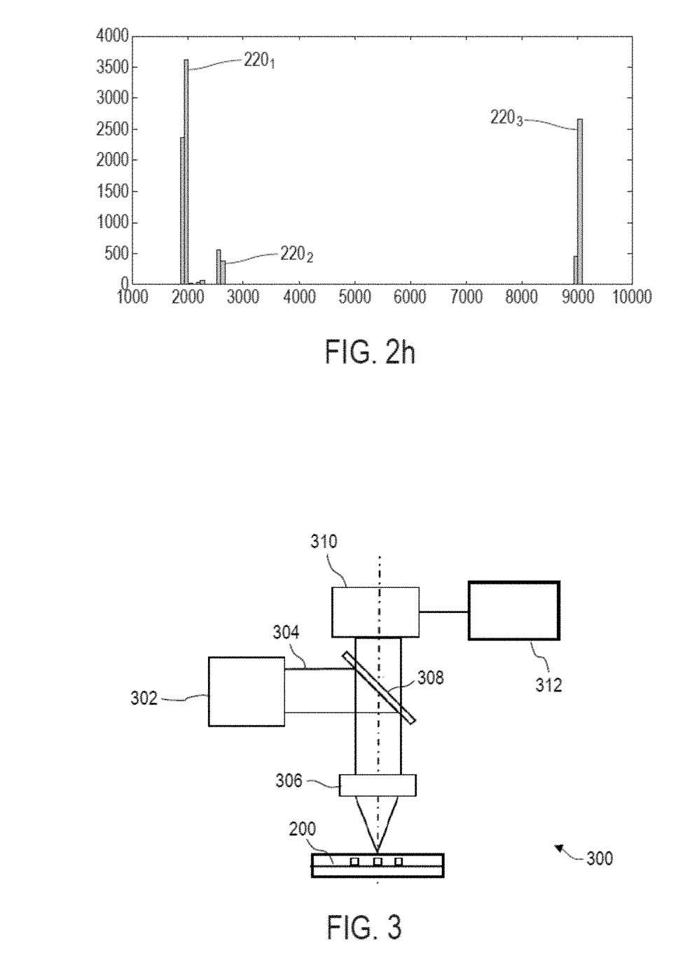

FIGS. 2a-2g give diagrammatic representations of an example of a face inspected according to the method according to the invention, such as for example the method 100 of FIG. 1.

In particular, the face 200, shown on FIG. 2a, is a face of a semiconductor comprising steps 202 and trenches 204.

FIG. 2b is an example of an interference signal measured for example in step 102 of the method 100 of the FIG. 1, at a point 206 located at the interface between a step 202 and a trench 204. The X-axis corresponds to the depth and the Y-axis corresponds to the intensity scale value of the camera (the greyscales of the camera). The measured interference signal 208, shown in FIG. 2b, comprises

two envelopes: envelope 210₁ corresponds to a step 202 and envelope 210₂ corresponds to a trench 204.

FIG. 2c is an example of two individual signals obtained, for example in step 108 of the method 100 of FIG. 1, after splitting the signal 208 in a splitting position 212, located between the envelopes 210₁ and 210₂, and equidistant from the positions of said envelopes 210₁ and 210₂. The individual signals 214₁ and 214₂ each comprise respectively envelope 210₁ and envelope 210₂.

FIG. 2d is an example of two signals 216₁ and 216₂ representing the phase of the Fourier transform, respectively of the individual signals 214₁ and 214₂ of FIG. 2c, obtained for example in step 110 of the method 100 of FIG. 1. It is noted that each signal 216₁ and 216₂ comprises a zone, 218₁ and 218₂ respectively, where the phase is substantially linear. Each linear zone 218₁ and 218₂ makes it possible to calculate the depth of the corresponding surface, namely, respectively of the step 202 or of the trench 204, for the measurement point 206.

FIG. 2d also gives an example of a signal 216₃ representing the phase of the Fourier transform of the measured interference signal 208. It is noted that in this case the phase does not comprise a linear zone making it possible to easily deduce an item of depth information therefrom.

FIG. 2e is an example of individual representation of each of the surfaces, namely a representation 218₁ of the surface formed by the steps 202 and a representation 218₂ of the surface formed by the trenches 204 and by the surface outside of the pattern, obtained for example in step 112 of the method 100 of FIG. 1. As seen in FIG. 2e, in the representations 218₁-218₂, certain measurement points have been allocated both to the surface formed by the steps 202 and that formed by the trenches 204. In particular, the measurement points for the trenches 204 located between the steps 202, have been allocated to each surface, as the representation 218₁ shows a continuous surface between the steps 202.

FIG. 2f is an example of a flat representation, and FIG. 2g is a three-dimensional representation of the inspected face 200, obtained

for example in step 122 of the method 100 of FIG. 1, after management of the contentious points in step 120.

It can be noted in particular that an in-plane representation of the pattern is obtained with a better localization of the transitions than in the original image in FIG. 2a, and therefore improved with respect to the resolution limit due to the imaging system. The three-dimensional representation in FIG. 2g illustrates the accuracy of the depth measurements obtained at each measurement point.

FIG. 2h shows a statistical analysis in the form of a histogram relating to all the measurement points, and the depth of these measurement points. It makes it possible in particular to see the depth distribution:
of the lower surface outside the pattern corresponding to peak 220₁;
of the lower surface inside the trenches corresponding to peak 220₂;
of the upper surface corresponding to peak 220₃.

FIG. 3 is a diagrammatic representation of a non-limitative embodiment example of a system according to the invention.

The system 300, shown in FIG. 3, comprises a light source 302, for example based on light-emitting diodes or a halogen source which generates a light beam 304 in the visible and/or near infrared wavelengths. This light beam 304 is directed towards a full-field interferometer 306 by a cube or beam splitter 308.

In the full-field interferometer 306, the light beam 304 is separated into a reference beam which illuminates a reference mirror and a measurement beam which illuminates a surface to be inspected, for example the surface 200 in FIG. 2a. The light reflected respectively by the surface 200 and by the reference mirror is redirected to a detector array 310, for example of CCD or CMOS type.

The system 300 comprises optics and lenses, including an imaging lens, arranged so as to image the surface 200 on the detector

array 310. When the difference in optical paths between the measurement beam and the reference beam is less than the coherence length of the light source 302, interference fringes due to the interferences between the measurement beam and the reference beam are also visible.

Different types of full-field interferometers 306 exist that can be used within the context of the invention, which are well known to a person skilled in the art and will not be detailed here.

The system 300 comprises moreover an electronic/computer module 312, such as a processor or an electronic chip or also a personal computer for example, connected to the detector array 310, and configured in order to implement all the steps of the method according to the invention, such as for example steps 104-122 of the method 100 of FIG. 1.

Of course, the invention is not limited to the examples which have just been described and numerous adjustments can be made to these examples without exceeding the scope of the invention.

1. A method for the inspection and measurement of a face of an object comprising at least two surfaces staggered depthwise with respect to one another, said surfaces forming in particular a step or a trench on or in said face, said method comprising the following steps:
measuring an interferometric signal, called measured signal, at several points, called measurement points, of said inspected face;
for at least one measurement point, extracting the measured signal relative to at least one, in particular to each, surface, said extraction providing for said measurement point an interferometric signal, called individual signal, for said surface; and
profilometric analysis of the individual signals, independently for each surface.

2. The method according to claim 1, characterized in that the measurement step carries out a measurement of an interferometric signal for each pixel of a sensor carrying out a full-field measurement, each pixel corresponding to a measurement point.

3. The method according to claim 1, characterized in that it comprises moreover a step, of independently constructing each surface as a function of the profilometric analysis of the individual signals from said surface.

4. The method according to claim 1, characterized in that it comprises moreover a step of construction of a representation of the inspected face.

5. The method according to claim 3, characterized in that the step of construction of a representation of the inspected face is carried out from of the individual representations of the surfaces, said step comprising, for at least one measurement point, an iteration of the following steps:
determining a signal quality value, at said measurement point, in at least two individual representations; and
allocating said measurement point to one of said surfaces, as a function of the signal quality values obtained for each of said two individual representations.

6. The method according to claim 5, characterized in that the allocation step is carried out by a predetermined comparison relationship taking into account:
the signal quality values of each individual representation; and
a multiplier coefficient applied to a signal quality value of an individual representation.

7. The method according to claim 1, characterized in that, for at least one surface, the profilometric analysis step comprises, for each individual signal:
a Fourier transform of said individual signal; and
an analysis of the phase of the Fourier transform obtained.

8. The method according to claim 1, characterized in that, for at least one surface, the step of extraction of a measured signal relating to said surface comprises a selection of a portion of said measurement signal comprising an envelope corresponding to said surface in said measurement signal.

9. The method according to claim 8, characterized in that, for two adjacent surfaces of different depths, the selection step produces a splitting of the measured signal into two portions each comprising an envelope corresponding to one of said surfaces in said measured signal, the individual signal for each surface corresponding to one of said portions.

10. The method according to claim 9, characterized in that the splitting of the measured signal, for two adjacent envelopes, is carried out in a position in said measured signal:
located between said two adjacent envelopes; and
substantially equidistant from the positions of said adjacent envelopes.

11. The method according to claim 8, characterized in that it comprises a step of estimating the position, in the measured signal, of at least one envelope corresponding to a surface, prior to the extraction step.

12. The method according to claim 11, characterized in that the step of estimating the position of an envelope in the measured signal comprises a step of:
demodulation of the measured signal;
analysis of the energy of the measured signal; and/or
analysis of contrast of the fringes of the measured signal.

13. A system for the inspection and measurement of a face of an object comprising at least two surfaces staggered depthwise with respect to one another, said surfaces forming in particular a step or a trench on or in said face, said system comprising:
a device for measuring an interferometric signal, called measured signal, at several points, called measurement points, of said inspected face; and
a module for processing the measured interferometric signals, configured for implementing all the steps of the method according to claim 1.

14. The system according to claim 13, characterized in that the measurement device comprises a full-field interferometric sensor.

15. Use:
of the method according to claim 1, or
of the system according to claim 13;
for the inspection of a face of a semiconductor or a wafer, in particular for measuring the depth(s) of trench(es) and/or the height(s) of step(s) present in/on said face.
